(19) United States
(12) Patent Application Publication
(10) Pub. No.: US 2013/0342259 A1
(43) Pub. Date: Dec. 26, 2013

(54) SEMICONDUCTOR INTEGRATED CIRCUIT AND SWITCHING DEVICE

(71) Applicant: KABUSHIKI KAISHA TOSHIBA, Tokyo (JP)

(72) Inventor: Takayuki TERAGUCHI, Kanagawa (JP)

(73) Assignee: Kabushiki Kaisha Toshiba, Tokyo (JP)

(21) Appl. No.: 13/758,210

(22) Filed: Feb. 4, 2013

(30) Foreign Application Priority Data
Jun. 20, 2012 (JP) 2012-138917

(51) Int. Cl. H03K 3/012

(52) U.S. Cl. CPC H03K 3/012
USPC 327/333

(57) ABSTRACT

A semiconductor circuit for supplying a signal for controlling a switching circuit includes a control terminal for receiving a control signal. The control signal is sent to a first inverter, which inverts the control signal to generate a first signal. The first signal is provided to a second inverter, which inverts the first signal to generate a second signal. A level shift circuit is configured to receive a first intermediate voltage and a second intermediate voltage and shifts levels of first and second intermediate voltages to generate first and second output voltages, respectively. The output voltages are received by an augmenting circuit, which also receives the first and second signals. The augmenting circuit is configured to augment the output voltages to generate first and second augmented voltages that are output to first and second output terminals, respectively.

### CROSS-REFERENCE TO RELATED APPLICATION

This application is based upon and claims the benefit of priority from Japanese Patent Application No. 2012-138917, filed Jun. 20, 2012, the entire contents of which are incorporated herein by reference.

### FIELD

Embodiments described herein relate generally to a semiconductor integrated circuit and a switching device.

### BACKGROUND

In related art switching devices, a level shift circuit supplies an internal voltage that is generated by a voltage boosting/lowering circuit. In consideration of the voltage rating of the device, the logic circuit is driven by a voltage in the range of, for example, 0 V to 1.5 V. The level shift circuit converts an incoming voltage in the range of 0 V to 1.5 V to, for example, an outgoing voltage in the range of −1.5 V to 3 V.

### DESCRIPTION OF THE DRAWINGS

FIG. 1 is a circuit diagram illustrating an example of a semiconductor integrated circuit according to a first embodiment.

FIG. 2 is a circuit diagram illustrating an example of an operation state of the semiconductor integrated circuit wherein a control signal is at a Low level.

FIG. 3 is a circuit diagram illustrating an example of the operation state of the semiconductor integrated circuit wherein the control signal is changed from the Low level to a High level.

FIG. 4 is a circuit diagram illustrating an example of the operation state of the semiconductor integrated circuit wherein the control signal is changed from the High level to the Low level.

FIG. 5 is a diagram illustrating a relationship between an output voltage and time for various input voltages for a comparative example.

FIG. 6 is a diagram illustrating a relationship between a current flowing in the input voltage terminal and time for various input voltages for the comparative example.

FIG. 7 is a diagram illustrating a relationship between an output voltage and time for various input voltages for the semiconductor integrated circuit according to the first embodiment.

FIG. 8 is a diagram illustrating a relationship between the current flowing to a second input voltage terminal and time for various input voltages for of the semiconductor integrated circuit according to the first embodiment.

FIG. 9 is a circuit diagram illustrating a switching device wherein the semiconductor integrated circuit according to the first embodiment is adopted.

FIG. 10 is a circuit diagram of a semiconductor integrated circuit according to a second embodiment.

### DETAILED DESCRIPTION

Embodiments of the present disclosure provide a semiconductor integrated circuit and a switching device with improved switching characteristics. In general, embodiments will be explained with reference to drawings.

A semiconductor integrated circuit for supplying a signal for controlling a switching circuit includes a control terminal for receiving a control signal. The control signal is sent to a first inverter which inverts the control signal to generate a first signal. The first signal is provided to a second inverter which generates a second signal by inverting the first signal. A level shift circuit is configured to receive a first intermediate voltage and a second intermediate voltage and provide a first output voltage by shifting a level of the first intermediate voltage and a second output voltage by shifting a level of the second intermediate voltage. The output voltages are received by an augmenting circuit, which also receives the first and second signals. The augmenting circuit is configured to change (or augment) output voltages to provide a first augmented voltage to a first output terminal and a second augmented voltage to a second output terminal.

An integrated circuit outputs a switch signal for controlling a switching circuit. The switch signal corresponds to a control signal which is input to the integrated circuit. The integrated circuit has a first level shift circuit that works as follows: in a first case, when the control signal changes from a first signal level to a second signal level, a voltage at a first output terminal is changed from a first potential to a second potential that is higher than the first potential, and a voltage at a second output terminal is changed from the second potential to the first potential; in a second case, when the control signal is changed from the second signal level to the first signal level, the first output terminal voltage is changed from the second potential to the first potential, and the second output terminal voltage is changed from the first potential to the second potential. Also, the integrated circuit has an augmenting circuit that works as follows: when the control signal changes from the first signal level to the second signal level, an increase of the first output terminal voltage from the first potential to the second potential is augmented, and a decrease of the second output terminal voltage from the second potential to the first potential is augmented; when the control signal is changed from the second signal level to the first signal level, a decrease of the first output terminal voltage from the second potential to the first potential is augmented, and an increase of the second output terminal voltage from the first potential to the second potential is augmented.

### First Embodiment

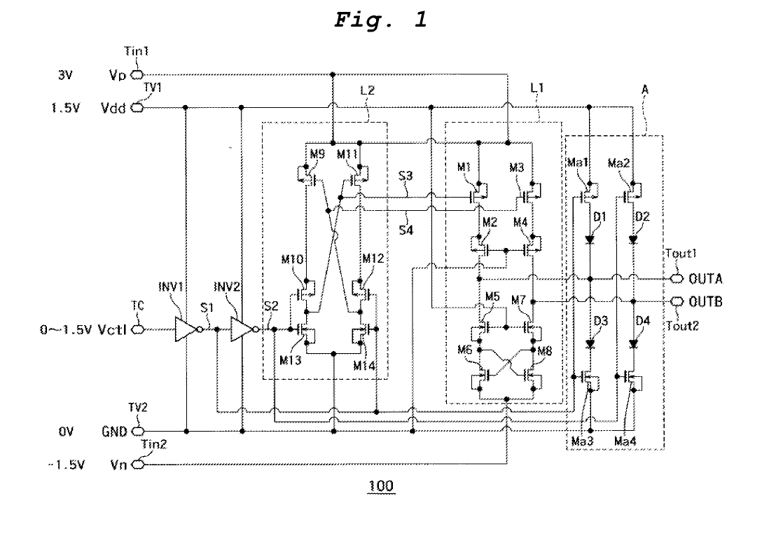

FIG. 1 is a circuit diagram illustrating an example of a constitution of a semiconductor integrated circuit 100 according to the first embodiment.

As shown in FIG. 1, the semiconductor integrated circuit 100 has a first inverter INV1, a second inverter INV2, a first level shift circuit L1, a second level shift circuit L2, and an augmenting circuit A.

The semiconductor integrated circuit 100 outputs a switch signal for controlling a switching circuit (not shown in the figure) at first and second output terminals Tout1 and Tout2, the switch signal corresponds to a control signal Vct1.

In addition, a first power supply terminal TV1 is supplied with a power supply voltage Vdd. A second power supply terminal TV2 is supplied with a ground voltage GND.

A first input voltage terminal Tin1 is supplied with voltage Vp obtained by boosting the power supply voltage Vdd (that is, at a voltage higher than the power supply voltage Vdd). Here, for example, the voltage Vp is 3 V.

Also, a second input voltage terminal Tin2 is supplied with a voltage Vn obtained by lowering the ground voltage GND (that is, a voltage lower than the ground voltage GND). Here, for example, the voltage Vn is −1.5 V.

As shown in FIG. 1, the first inverter INV1 has its input connected to a control terminal TC. This first inverter INV1 has the control signal Vct1 input to it via the control terminal TC, and the first inverter INV1 outputs a first signal S1.

The second inverter INV2 has its input connected to an output of the first inverter INV1. The second inverter INV2 receives the first signal S1 as input and outputs a second signal S2.

Here, the first and second inverters INV1, INV2 are driven by the power supply voltage Vdd.

The second level shift circuit L2 receives the first and second signals S1, S2 as input. The second level shift circuit L2 then outputs a third signal S3 (first intermediate voltage), which is obtained by shifting the level of the first signal S1, and a fourth signal S4 (second intermediate voltage), obtained by shifting the level of the second signal S2.

For example, the second level shift circuit L2 works as follows: in a first case when the control signal Vct1 is changed from a first signal level to a second signal level, it changes the third signal S3 from a High level (3 V) to a Low level (0 V); additionally, it changes the fourth signal S4 from the Low level (0 V) to the High level (3 V).

On the other hand, in a second case when the control signal Vct1 is changed from the second signal level to the first signal level, the second level shift circuit L2 changes the third signal S3 from the Low level (0 V) to the High level (3 V), and it changes the fourth signal S4 from the High level (3 V) to the Low level (0 V).

Here, the first signal level is the Low level (such as the ground voltage GND, which is 0 V). The second signal level is the High level (such as the power supply voltage Vdd, which is, for example, 1.5 V).

The first level shift circuit L1 receives the third and fourth signals S3, S4 as input.

In the first case when the control signal Vct1 is changed from the first signal level to the second signal level, the first level shift circuit L1 has the voltage at the first output terminal Tout1 changed from the first potential to the second potential, which is higher than the first potential; it also has the second output terminal Tout2 changed from the second potential to the first potential.

On the other hand, in the second case when the control signal Vct1 is changed from the second signal level to the first signal level, the first level shift circuit L1 has the first output voltage changed from the second potential to the first potential; it also has the voltage of the second output terminal Tout2 changed from the first potential to the second potential.

That is, the first level shift circuit L1 changes the voltages at the first and second output terminals Tout1, Tout2 corresponding to the third and fourth signals S3, S4.

Here, the first potential may be at −1.5 V, and the second potential may be at 3 V.

Also, the augmenting circuit A has the first and second signals S1, S2 input to it. The augmenting circuit A is connected between the first power supply terminal TV1 and the second power supply terminal TV2. That is, the augmenting circuit A has the power supply voltage Vdd supplied to it.

In the first case, the augmenting circuit A augments an increase of the voltage at the first output terminal Tout1 from the first potential, and it augments a decrease of the voltage at the second output terminal Tout2 from the second potential.

On the other hand, in the second case, the augmenting circuit A augments a decrease of the voltage at the first output terminal Tout1 from the second potential, and it augments an increase of the voltage at the second output terminal Tout2 from the first potential.

That is, the augmenting circuit A augments changes in the voltages at the first and second output terminals Tout1, Tout2 that correspond to the first and second signals S1, S2. The augmenting circuit A supplies augmented voltages at the first and second output terminals to provide faster transitions between output voltage levels when the control signal changes.

Here, as shown in FIG. 1, for example, the augmenting circuit A has a first augmenting MOS transistor (pMOS transistor) Ma1 of a first electroconductive (conductivity) type; a second augmenting MOS transistor (pMOS transistor) Ma2 of the first electroconductive type; a third augmenting MOS transistor (nMOS transistor) Ma3 of a second electroconductive type; a fourth augmenting MOS transistor (nMOS transistor) Ma4 of the second electroconductive type; a first diode D1, a second diode D2, a third diode D3, and a fourth diode D4.

The first augmenting MOS transistor Ma1 has its source connected to the first power supply terminal TV1 and has its gate connected to the output of the first inverter INV1.

The first diode D1 has its anode connected to a drain of the first augmenting MOS transistor Ma1 and has its cathode connected to the first output terminal Tout1.

The second augmenting MOS transistor Ma2 has its source connected to the first power supply terminal TV1, and has its gate connected to the output of the second inverter INV2.

The second diode D2 has its anode connected to a drain of the second augmenting MOS transistor Ma2 and has its cathode connected to the second output terminal Tout2.

The third augmenting MOS transistor Ma3 has its source connected to the second power supply terminal TV2, and has its gate connected to an output of the first inverter INV1.

The third diode D3 has its cathode connected to a drain of the third augmenting MOS transistor Ma1, and it has its anode connected to the first output terminal Tout1.

The fourth augmenting MOS transistor Ma4 has its source connected to the second power supply terminal TV2, and it has its gate connected to an output of the second inverter INV2.

The fourth diode D4 has its cathode connected to a drain of the fourth augmenting MOS transistor Ma4, and it has its anode connected to the second output terminal Tout2.

Also, as shown in FIG. 1, for example, the first-level shift circuit L1 has a first MOS transistor (pMOS transistor) M1 of the first electroconductive type; a second MOS transistor (pMOS transistor) M2 of the first electroconductive type; a third MOS transistor (pMOS transistor) M3 of the first electroconductive type, a fourth MOS transistor (pMOS transistor) M4 of the first electroconductive type; a fifth MOS transistor (nMOS transistor) M5 of the second electroconductive type, a sixth MOS transistor (nMOS transistor) M6 of the second electroconductive type; a seventh MOS transistor (nMOS transistor) M7 of the second electroconductive type; and the eighth MOS transistor (nMOS transistor) M8 of the second electroconductive type.

The first MOS transistor M1 has its source connected to the first input voltage terminal Tin1.

The second MOS transistor M2 has its source connected to a drain of the first MOS transistor M1, has its drain connected to the first output terminal Tout1, and has the gate connected to the second power supply terminal TV2.

The third MOS transistor M3 has its source connected to the first input voltage terminal Tin1.

The fourth MOS transistor M4 has its source connected to the drain of the third MOS transistor M3, has its drain connected to the second output terminal Tout2, and has its gate connected to the second power supply terminal TV2.

The fifth MOS transistor M5 has its drain connected to the first output terminal Tout1 and has its gate connected to the first power supply terminal TV1.

The sixth MOS transistor M6 has the drain connected to the source of the fifth MOS transistor M5 and has its source connected to the second power supply terminal TV2.

The seventh MOS transistor M7 has its drain connected to the second output terminal Tout2, has its source connected to the gate of the sixth MOS transistor M6, and has its gate connected to the gate of the fifth MOS transistor M5.

The eighth MOS transistor M8 has its drain connected to the source of the seventh MOS transistor M7, has its source connected to the second power supply terminal TV2, and has its gate connected to the source of the fifth MOS transistor M5.

In addition, as shown in FIG. 1, the second level shift circuit L2, for example, has a ninth MOS transistor (pMOS transistor) M9 of the first electroconductive type; a tenth MOS transistor (pMOS transistor) M10 of the first electroconductive type, a eleventh MOS transistor (pMOS transistor) M11 of the first electroconductive type; a twelfth MOS transistor (pMOS transistor) M12 of the first electroconductive type; a thirteenth MOS transistor (nMOS transistor) M13 of the second electroconductive type; and a fourteenth MOS transistor (nMOS transistor) M14 of the second electroconductive type.

The ninth MOS transistor M9 has its source connected to the first input voltage terminal Tin1 and has its gate connected to the gate of the third MOS transistor M3.

The tenth MOS transistor M10 has its source connected to the drain of the ninth MOS transistor M9, has its drain connected to the gate of the first MOS transistor M1, and has its gate connected to the output of the second inverter INV2.

The eleventh MOS transistor M11 has its source connected to the first input voltage terminal Tin1 and has its gate connected to the gate of the first MOS transistor M1.

The twelfth MOS transistor M12 has its source connected to a drain of the eleventh MOS transistor M11, has its drain connected to the gate of the ninth MOS transistor M9, and has its gate connected to the output of the first inverter INV1.

The thirteenth MOS transistor M13 has its drain connected to a drain of the 10th MOS transistor M10, has its source connected to the second power supply terminal TV2, and has its gate connected to the output of the second inverter INV2.

The fourteenth MOS transistor M14 has its drain connected to a drain of the twelfth MOS transistor M12, has its source connected to the second power supply terminal TV2, and has its gate connected to the output of the first inverter INV1.

In addition, as shown in FIG. 1, the first through fourth first augmenting MOS transistors Ma1 to Ma4 and the first through the fourteenth MOS transistors M1 to M14 each have the back gate connected to the source.

In the following, an example of the operation of the semiconductor integrated circuit 100 having the constitution will be explained.

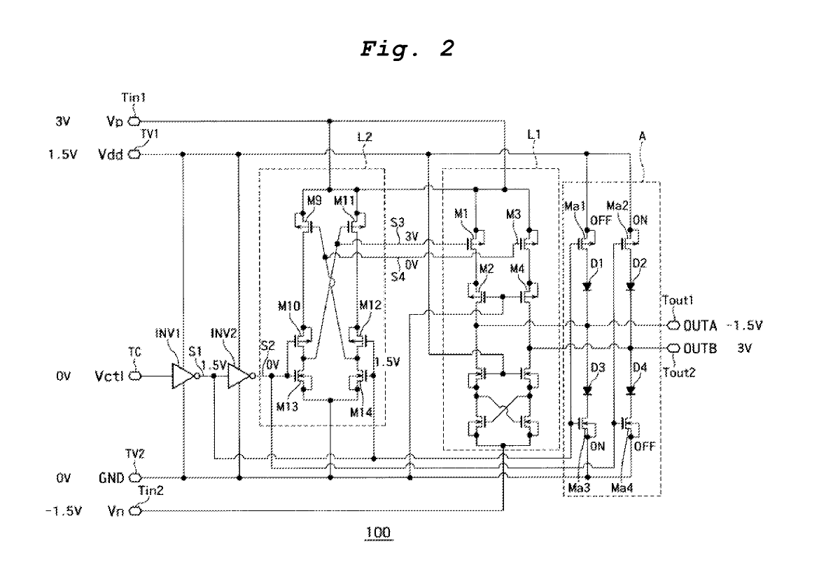

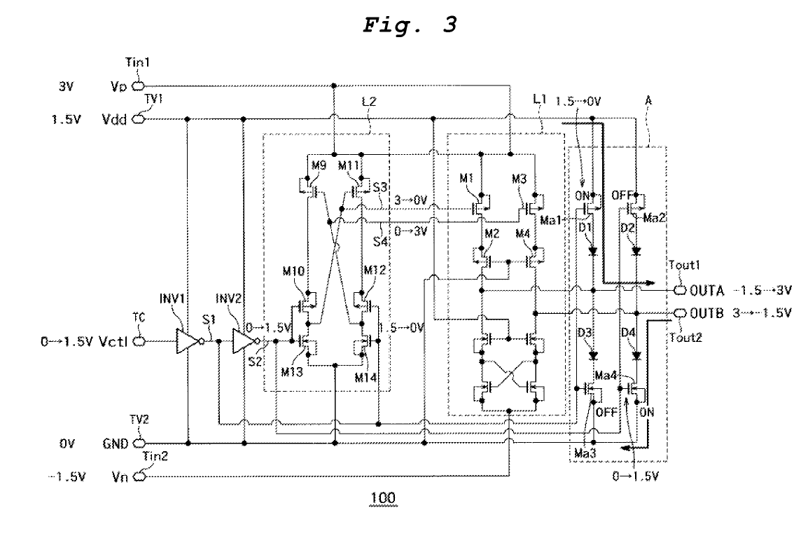

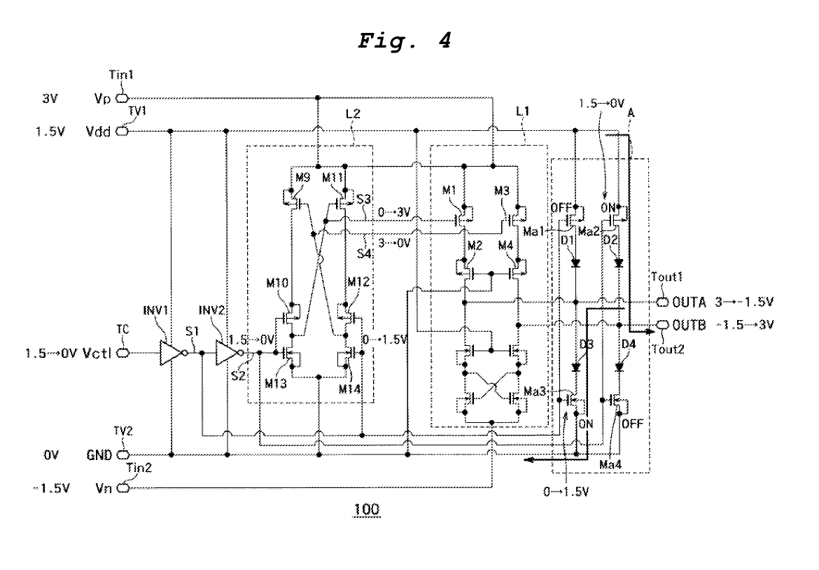

Here, FIG. 2 is a circuit diagram illustrating an example of the operation state of the semiconductor integrated circuit 100 with the control signal Vct1 on the Low level. FIG. 3 is a circuit diagram illustrating an example of the operation state of the semiconductor integrated circuit 100 with the control signal Vct1 changed from the Low level to the High level . FIG. 4 is a circuit diagram illustrating an example of the operation state of the semiconductor integrated circuit 100 with the control signal Vct1 changed from the High level to the Low level.

First of all, in a normal state, as shown in FIG. 2, the control signal Vct1 on the Low level (here, 0 V) is input into the control terminal Tc.

In this case, the first inverter INV1 outputs the first signal S1 on the High level (here, 1.5 v). In addition, the second inverter INV2 outputs the second signal S2 on the Low level (here, 0 V).

Then, corresponding to the first and second signals S1, S2, the second level shift circuit L2 outputs the third signal S3 on the High level (3 V), and it outputs the fourth signal S4 on the Low level (0 V).

Then, corresponding to the third and fourth signals S3, S4, the first-level shift circuit L1 sets the voltage at the first output terminal Tout1 at the first potential (−1.5 V); at the same time, it sets the voltage at the second output terminal Tout2 at the second potential (3 V).

In addition, corresponding to the first and second signals S1, S2, the augmenting circuit A turns off the first and fourth first augmenting MOS transistors Ma1, Ma4 and turns on the second and third second augmenting MOS transistors Ma2, Ma1. That is, the augmenting circuit A sets the voltage at the first output terminal Tout1 at the first potential (−1.5 V); at the same time, it sets the voltage at the second output terminal Tout2 at the second potential (3 V).

When, as shown in FIG. 3, the control signal Vct1 is changed from the Low level to the High level, the first inverter INV1 changes the first signal S1 from the High level to the Low level. In addition, the second inverter INV2 changes the second signal S2 from the Low level to the High level.

Then, corresponding to the first and second signals S1, S2, the second level shift circuit L2 changes the third signal S3 from the High level to the Low level, and it changes the fourth signal S4 from the Low level to the High level.

Then, corresponding to the third and fourth signals S3, S4, the first level shift circuit L1 changes the voltage at the first output terminal Tout1 from the first potential to the second potential; at the same time, it changes the voltage at the second output terminal Tout2 from the second potential to the first potential.

In addition, corresponding to the first and second signals S1, S2, the augmenting circuit A turns on the first and fourth first augmenting MOS transistors Ma1, Ma4, and it turns off the second and third second augmenting MOS transistors Ma2, Ma1.

As a result, the augmenting circuit A increases the voltage at the first output terminal Tout1 from the first potential to the third potential between the first potential and the second potential (power supply voltage Vdd—forward voltage Vf); it also decreases the voltage at the second output terminal Tout2 from the second potential to the fourth potential between the first potential and the second potential (forward voltage Vf).

That is, the augmenting circuit A augments an increase of the voltage at the first output terminal Tout1 from the first potential, and it augments a decrease of the voltage at the second output terminal Tout2 from the second potential.

Then, as shown in FIG. 4, the control signal Vct1 changes from the High level to the Low level.

In this case, the first inverter INV1 changes the first signal S1 from the Low level to the High level. In addition, the second inverter INV2 changes the second signal S2 from the High level to the Low level.

Corresponding to the first and second signals S1, S2, the second-level shift circuit L2 changes the third signal S3 from the Low level to the High level, and it changes the fourth signal S4 from the High level to the Low level.

Then, corresponding to the third and fourth signals S3, S4, the first-level shift circuit L1 changes the voltage at the first output terminal Tout1 from the second potential to the first potential; at the same time, it changes the voltage at the second output terminal Tout2 from the first potential to the second potential.

In addition, corresponding to the first and second signals S1, S2, the augmenting circuit A turns off the first and fourth first augmenting MOS transistors Ma1, Ma4, and it turns on the second and third second augmenting MOS transistors Ma2, Ma1.

As a result, the augmenting circuit A decreases the voltage at the first output terminal Tout1 from the second potential to the fourth potential (forward voltage Vf), and it increases the voltage at the second output terminal Tout2 from the first potential to the third potential (power supply voltage Vdd—forward voltage Vf).

That is, the augmenting circuit A augments a decrease of the voltage at the first output terminal Tout1 from the second potential, and it augments an increase of the voltage at the second output terminal Tout2 from the first potential.

By the operation of the semiconductor integrated circuit 100 and independent of the potential at the input voltage terminal, it is possible to switch reliably the output voltages OUTA, OUTB at the first and second output terminals Tout1, Tout2 to the prescribed values. That is, it is possible to improve the switching property of the switching circuit controlled by the output voltages OUTA, OUTB.

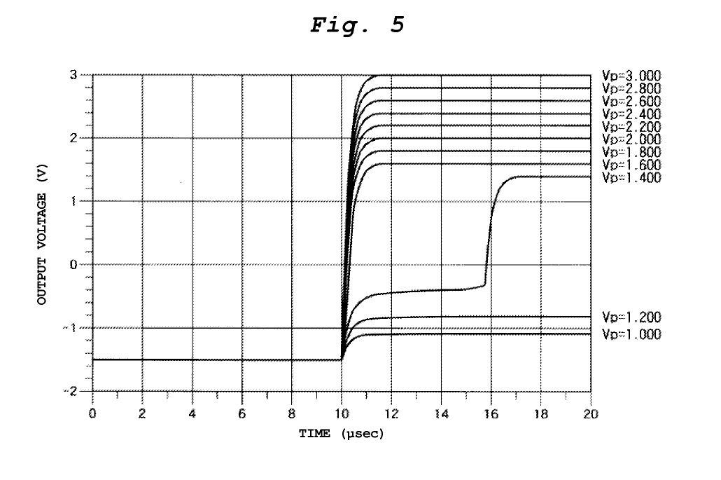

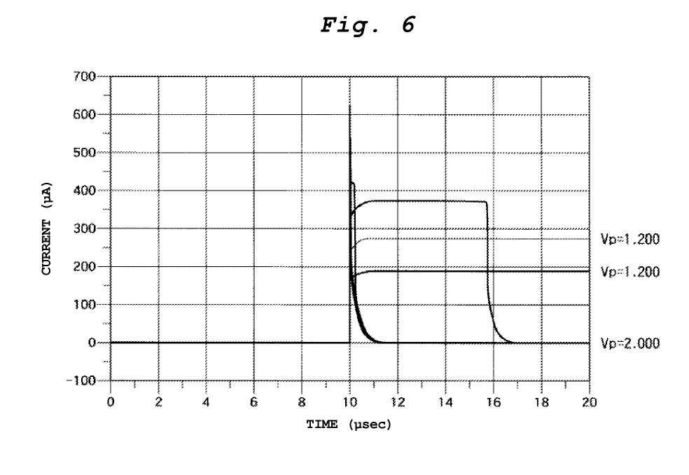

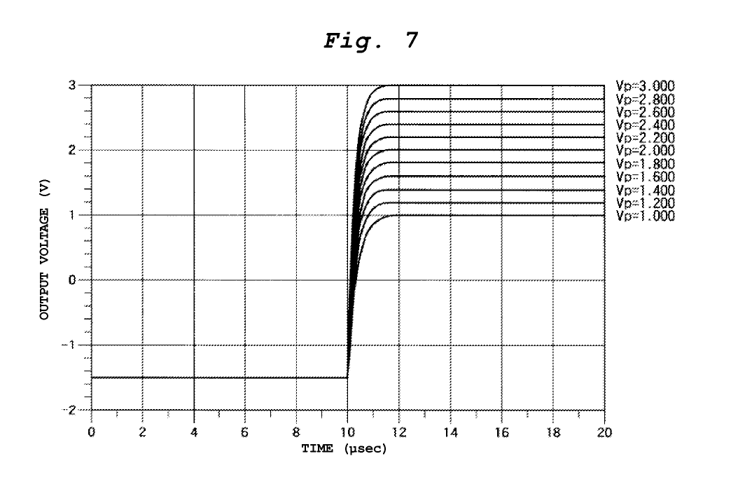

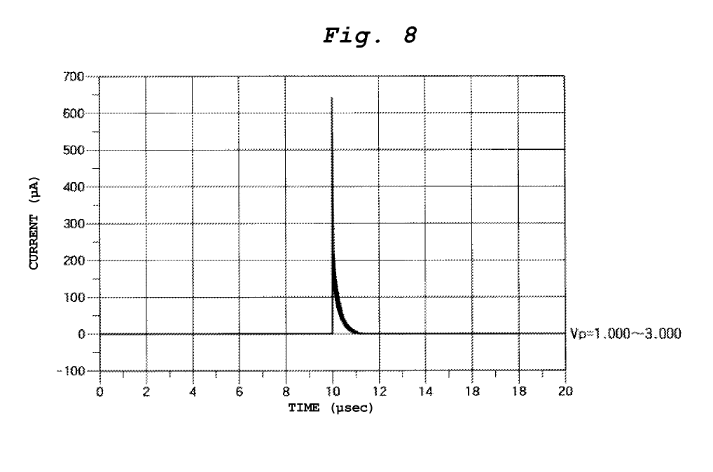

Here, FIG. 5 is a diagram illustrating characteristics in an example of a relationship between the output voltage and the input voltage in a comparative example. FIG. 6 is a diagram illustrating characteristics in an example of a relationship between the current flowing at the input voltage terminal and the input voltage in the comparative example. FIG. 7 is a diagram illustrating characteristics of an example of a relationship between the output voltage OUTA and the voltage Vp of the semiconductor integrated circuit 100 according to the first embodiment. FIG. 8 is a diagram illustrating characteristics of an example of a relationship between the current flowing at the second input voltage terminal Tin2 and the voltage Vp of the semiconductor integrated circuit 100 according to the first embodiment. As shown in FIG. 5 to FIG. 8, the control signal Vct1 varies at 10 μs. The constitution in the comparative example omits the augmenting circuit from the semiconductor integrated circuit 100.

As shown in FIG. 5 and FIG. 6, in the comparative example not having the augmenting circuit, when the voltage Vp decreases (such as when Vp=1.0 V, 1.2 V), switching of the output voltage caused by change in the control signal Vct1 is insufficient.

On the other hand, as shown in FIG. 7 and FIG. 8, the semiconductor integrated circuit 100 according to the first embodiment can switch the output power over a prescribed value by changing the control signal Vct1 even when the voltage Vp decreases (for example, when Vp=1.0 V, 1.2 V).

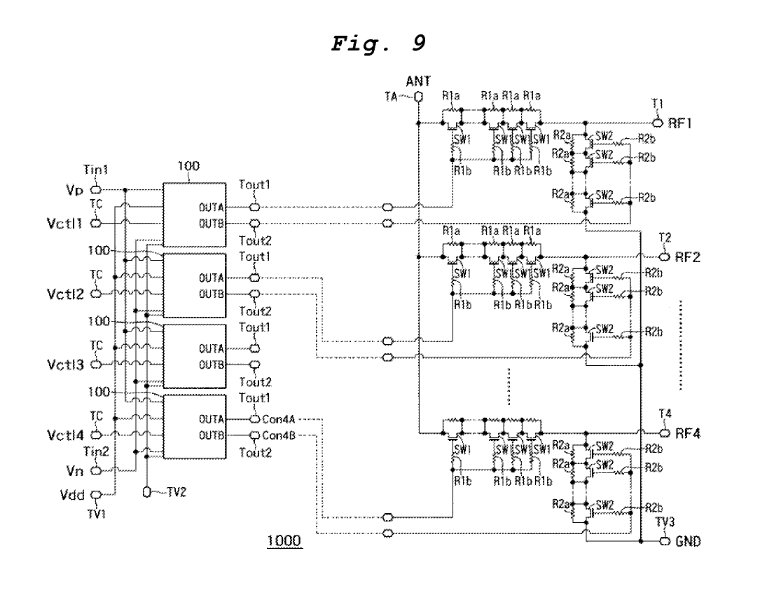

In the following, an example of the constitution of the circuit of the switching device adopting the semiconductor integrated circuit 100, shown in FIG. 1, will be explained. FIG. 9 is a circuit diagram illustrating an example of the circuit constitution of the switching device 1000 that adopts the semiconductor integrated circuit 100, as shown in FIG. 1.

As shown in FIG. 9, the switching device 1000 has plural first switching circuits SW1, plural second switching circuits SW2, plural resistors R1a, R1b, R2a, R2b, and plural semiconductor integrated circuit 100.

A first group of first switching circuits SW1 are connected in tandem between a common terminal TA and an input/output terminal T1. Similarly, plural second group of first switching circuits SW1 are connected in tandem between the common terminal TA and an input/output terminal T2. Also, in the same way, the respective groups of first switching circuits SW1 are connected in tandem between the common terminal TA and an a respective input/output terminal (e.g., T4 for the fourth group of first switching circuits SW1).

As shown in FIG. 9, the first switching circuits SW1 are, for example, nMOS transistors.

A resistor R1a is connected between the source and drain of each first switching circuit SW1.

A resistor R1b is connected between the gate of each first switching circuit SW1 and the first output terminal Tout1.

A first group of second switching circuits SW2 are connected in tandem between a ground terminal TV3 and the input/output terminal T1. Similarly, a second group of second switching circuits SW2 are connected between the ground terminal TV3 and the input/output terminal T2. Also, the a respective group of second switching circuits SW2 are connected in tandem between the ground terminal TV3 and the respective input/output terminal (for example, T4 for the fourth group of second switching circuits).

As shown in FIG. 9, the second switching circuits SW2 are, for example, nMOS transistors.

A resistor R2a is connected between the source and drain of each second switching circuit SW2.

A resistor R2b is connected between the gate of each second switching circuit SW2 and the second output terminal Tout2.

Corresponding to the control signals Vct11 to Vct14, the respective semiconductor integrated circuit 100 outputs the signal for controlling the plural first switching circuits SW1 from the first output terminal Tout1 to the gates of the respective group of first switching circuits SW1,; additionally, the respective semiconductor integrated circuit 100 outputs the signal for controlling the plural second switching circuits SW2 from the second output terminal Tout2 to the gates of the respective group of second switching circuits SW2.

Here, as previously explained, independent of the potential at the input voltage terminal, the semiconductor integrated circuit 100 can reliably switch the output voltages OUTA, OUTB of the first and second output terminals Tout1, Tout2 to the prescribed values.

That is, by adopting the semiconductor integrated circuit 100 in the switching device 1000, it is possible to quickly switch the various switching circuits SW1, SW2 even when variation takes place in the input voltages Vp, Vn (boosted/decreased voltages).

As previously explained, for the semiconductor integrated circuit and switching device according to the present embodiment, it is thus possible to improve the switching property of the switching circuit.

### Second Embodiment

In the following, describing the second embodiment, an example of the constitution wherein the first input voltage terminal Tin1 and the first power supply terminal TV1 are shared/connected will be explained.

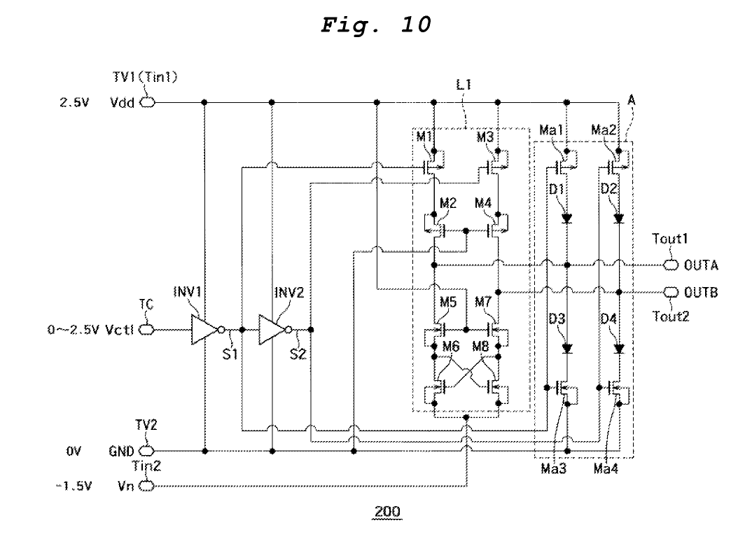

FIG. 10 is a circuit diagram illustrating an example of the constitution of a semiconductor integrated circuit 200 according to the second embodiment. The same keys as those in the above in the first embodiment, which is shown in FIG. 1, are adopted here in FIG. 10. As previously explained, as shown in FIG. 10, the first input voltage terminal Tin1 and the first power supply terminal TV1 are similar to each other. The semiconductor integrated circuits 200 can also adopted in the switching device 1000 depicted in FIG. 9.

As shown in FIG. 10, the semiconductor integrated circuit 200 has the first inverter INV1, the second inverter INV2, the first level shift circuit L1 and the augmenting circuit A. This semiconductor integrated circuit 200 omits the second-level shift circuit L2 as opposed to the first embodiment.

As previously explained, the first input voltage terminal Tin1 is shared with or connected to the first power supply terminal TV1. The first power supply terminal TV1 has the power supply voltage Vdd fed to it just as in the first embodiment.

Also, as in the first embodiment, the second power supply terminal TV2 has the ground voltage GND fed to it.

In addition, the second input voltage terminal Tin2 has the voltage Vn decreased from the ground voltage GND (that is, a voltage lower than the ground voltage GND) fed to it. Here, the voltage Vn is, for example, −1.5 V.

Similarly in the first embodiment, the first inverter INV1 has its input connected to the control terminal TC. This first inverter INV1 has the control signal Vct1 input via the control terminal TC, and it outputs the first signal S1.

Also, the second inverter INV2 receives as input the output of the first inverter INV1. The second inverter INV2 has the first signal S1 input to it, and it outputs the second signal S2.

Corresponding to the first and second signals S1, S2, the first-level shift circuit L1 changes the voltages at the first and second output terminals Tout1, Tout2.

The augmenting circuit A has the first and second signals S1, S2 input to it. Here, the augmenting circuit A is connected between the first power supply terminal TV1 and the second power supply terminal TV2. That is, the augmenting circuit A has the power supply voltage Vdd supplied to it.

Corresponding to the first and second signals S1, S2, the augmenting circuit A augments changes in the voltages at the first and second output terminals Tout1, Tout2.

Here, just as in the first embodiment and as shown in FIG. 10, the first-level shift circuit L1 has the first MOS transistor M1 of the first electroconductive type (pMOS transistor); the second MOS transistor M2 of the first electroconductive type (pMOS transistor); the third MOS transistor M3 of the first electroconductive type (pMOS transistor); the fourth MOS transistor M4 of the first electroconductive type (pMOS transistor); the fifth MOS transistor M5 of the second electroconductive type (nMOS transistor), the sixth MOS transistor M6 of the second electroconductive type (nMOS transistor); the seventh MOS transistor M7 of the second electroconductive type (nMOS transistor); and the eighth MOS transistor M8 of the second electroconductive type (nMOS transistor).

The first MOS transistor M1 has its source connected to the first input voltage terminal Tin1 and has its gate connected to the output of the first inverter INV1.

The second MOS transistor M2 has its source connected to the drain of the first MOS transistor M1, has the drain connected to the first output terminal Tout1, and has its gate connected to the output of the second inverter INV2.

The third MOS transistor M3 has its source connected to the first input voltage terminal Tin1 and has its gate connected to the output of the second inverter INV2.

The fourth MOS transistor M4 has its source connected to the drain of the third MOS transistor M3, has its drain connected to the second output terminal Tout2, and has its gate connected to the second power supply terminal TV2.

The fifth MOS transistor M5 has its drain connected to the first output terminal Tout1 and has its gate connected to the first power supply terminal TV1.

The sixth MOS transistor M6 has its drain connected to the source of the fifth MOS transistor M5 and has its source connected to the second power supply terminal TV2.

The seventh MOS transistor M7 has its drain connected to the second output terminal Tout2, has its source connected to the gate of the sixth MOS transistor M6, and has its gate connected to the gate of the fifth MOS transistor M5.

The eighth MOS transistor M8 has its drain connected to the source of the seventh MOS transistor M7, has its source connected to the second power supply terminal TV2, and has its gate connected to the source of the fifth MOS transistor M5. The first through fourth first augmenting MOS transistors Ma1 to Ma4 and the first through eighth first augmenting MOS transistors M1 to M8 each have the bag gate connected to the source.

The other features of the constitution and functions of the semiconductor integrated circuit 200 are the same as those of the semiconductor integrated circuit 100 in the first embodiment.

Here, the operation of the semiconductor integrated circuit 200 is generally the same as that of the first embodiment.

That is, the first-level shift circuit L1 works as follows: in the first case when the control signal Vct1 is changed from the first signal level to the second signal level; the shift circuit L1 changes the voltage at the first output terminal Tout1 from the first potential to the second potential higher than the first potential; and changes the voltage at the second output terminal Tout2 from the second potential to the first potential.

In addition, the augmenting circuit A works as follows: in the first case, it augments an increase of the first output terminal Tout1 from the first potential, and augments a decrease of the second output terminal Tout2 from the second potential.

On the other hand, the first-level shift circuit L1 in this embodiment works as follows: in the second case when the control signal Vct1 changes from the second signal level to the first signal level, it changes the first output voltage from the second potential to the first potential, and it changes the voltage at the second output terminal Tout2 from the first potential to the second potential.

In this way, corresponding to the first and second signals S1, S2, the first-level shift circuit L1 changes the voltages at the first and second output terminals Tout1, Tout2.

In addition, the augmenting circuit A works as follows: in the second case, it augments a decrease of the voltage at the first output terminal Tout1 from the second potential, and it augments an increase of the second output terminal Tout2 from the first potential.

With the operation of the semiconductor integrated circuit 200, independent of the potential at the input voltage terminal, it is possible to reliably switch the output voltages OUTA, OUTB of the first and second output terminals Tout1, Tout2 . That is, it is possible to improve the switching property of the switching circuit controlled by the output voltages OUTA, OUTB.

That is, with the semiconductor integrated circuit and the switching device according to this embodiment, it is possible to improve the switching properties of the switching circuit.

However, the embodiments are merely examples, and the range of the present disclosure is not limited to them.

While certain embodiments have been described, these embodiments have been presented by way of example only and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A circuit for supplying a signal for controlling a switching circuit, comprising:
a control terminal for receiving a control signal;
a first inverter connected to the control terminal and configured to invert the control signal to generate a first signal;
a second inverter connected to the first inverter and configured to invert the first signal to generate a second signal;
a first level shift circuit receiving a first intermediate voltage and a second intermediate voltage and configured to shift a level of the first intermediate voltage to generate a first output voltage and to shift a level of the second intermediate voltage to generate a second output voltage; and
an augmenting circuit configured to augment levels of the first and second output voltages in response to changes in the first and second signals to generate first and second augmented voltages and output the first augmented voltage to a first output terminal and the second augmented voltage to a second output terminal.

2. The circuit of claim 1, wherein the augmenting circuit is configured to not augment the levels of the first and second output voltages when the first and second signals do not change so as to output the first output voltage to the first output terminal and the second output voltage to the second output terminal.

3. The circuit of claim 1, further comprising:
a second level shift circuit receiving the first signal and the second signal and configured to shift a level of the first signal to generate the first intermediate voltage and to shift a level of the second signal to generate the second intermediate voltage.

4. The circuit of claim 1, wherein a power supply voltage drives the first and second inverters.

5. The circuit of claim 4, further comprising:
a first power supply terminal supplied with the power supply voltage;
a first input voltage terminal supplied with first input voltage which is higher than the power supply voltage;
a second power supply terminal supplied with a ground voltage; and
a second input voltage terminal supplied with a voltage lower than the ground voltage.

6. The circuit of claim 4, further comprising:
a first power supply terminal supplied with the power supply voltage; and
a second power supply terminal supplied with a ground voltage,
wherein the augmenting circuit is connected between the first power supply terminal and the second power supply terminal.

7. The circuit of claim 1, further comprising:
a plurality of first switching circuits connected in series between a common terminal and an input/output terminal, wherein gates of the first switching circuits are provided with the first augmented voltage; and
a plurality of second switching circuits connected in series between a ground terminal and the input/output terminal, wherein gates of the second switching circuits are provided with the second augmented voltage.

8. The circuit of claim 1, wherein the augmenting circuit comprises:
a first augmenting MOS transistor of a first conductivity type having a source connected to a first power supply terminal and a gate connected to the first signal;
a first diode having an anode connected to a drain of the first augmenting MOS transistor and a cathode connected to the first output terminal;
a second augmenting MOS transistor of the first conductivity type having a source connected to the first power supply terminal and a gate connected to the second signal;
a second diode having an anode connected to a drain of the second augmenting MOS transistor and a cathode connected to the second output terminal;
a third augmenting MOS transistor of a second conductivity type having a source connected to a second power supply terminal and a gate connected to the first signal;
a third diode having a cathode connected to a drain of the third augmenting MOS transistor and an anode connected to the first output terminal;
a fourth augmenting MOS transistor of the second conductivity type having a source connected to the second power supply terminal and a gate connected to the second signal; and
a fourth diode having a cathode connected to a drain of the fourth augmenting MOS transistor and an anode connected to the second output terminal.

9. A semiconductor integrated circuit for supplying a signal for controlling a switching circuit, comprising:
a first-level shift circuit configured to shift a first output voltage from a first potential to a second potential higher than the first potential and a second output voltage from the second potential to the first potential when a control signal changes from a first signal level to a second signal level, and to shift the first output voltage from the second potential to the first potential and the second output voltage from the first potential to the second potential when the control signal changes from the second signal level to the first signal level; and
an augmenting circuit configured to augment the first output voltage and the second output voltage when the control signal changes.

10. The semiconductor integrated circuit according to claim 9, further comprising:
a first inverter configured to receive the control signal and to output a first signal;
a second inverter configured to receive the first signal and to output a second signal; and
a second-level shift circuit configured to shift a level of the first signal to generate a third signal and to shift the second signal to generate a fourth signal, wherein the first-level shift circuit is configured to change the first and second output voltages based on the third and fourth signals; and
the augmenting circuit is configured to augment changes in the first and second output voltages based on the first and second signals.

11. The semiconductor integrated circuit according to claim 9, further comprising:
a first inverter configured to receive the control signal input and to generate the first signal; and
a second inverter configured to receive the first signal input and to generate the second signal;
wherein the first-level shift circuit is configured to change the first and second output voltages based on the first and second signals; and
the augmenting circuit is configured to augment the first and second output voltages based on the first and second signals.

12. The semiconductor integrated circuit according to claim 10, wherein the augmenting circuit comprises:
a first augmenting MOS transistor of a first conductivity type that has a source connected to a first power supply terminal and a gate connected to an output of the first inverter;
a first diode that has an anode connected to a drain of the first augmenting MOS transistor and a cathode connected to the first output terminal;
a second augmenting MOS transistor of the first conductivity type that has a source connected to the first power supply terminal and a gate connected to an output of the second inverter;
a second diode that has an anode connected to a drain of the second augmenting MOS transistor and a cathode connected to the second output terminal;
a third augmenting MOS transistor of a second conductivity type that has a source connected to a second power supply terminal and a gate connected to the output of the first inverter;
a third diode that has a cathode connected to a drain of the third augmenting MOS transistor and an anode connected to the first output terminal;
a fourth augmenting MOS transistor of the second conductivity type that has a source connected to the second power supply terminal and a gate connected to the output of the second inverter; and
a fourth diode that has a cathode connected to a drain of the fourth augmenting MOS transistor and an anode connected to the second output terminal.

13. The semiconductor integrated circuit according to claim 12, wherein the first-level shift circuit comprises:
a first MOS transistor of the first conductivity type having a source connected to a first input voltage terminal and a gate connected to the output of the first inverter;
a second MOS transistor of the first conductivity type having a source connected to a drain of the first MOS transistor, a drain connected to the first output terminal, and a gate connected to the output of the second inverter;
a third MOS transistor of the first conductivity type having a source connected to the first input voltage terminal and a gate connected to the output of the second inverter;
a fourth MOS transistor of the first conductivity type having a source connected to a drain of the third MOS transistor, a drain connected to the second output terminal, and a gate connected to the second power supply terminal;
the fifth MOS transistor of the second conductivity type having a drain connected to the first output terminal and a gate connected to the first power supply terminal;
the sixth MOS transistor of the second conductivity type having a drain connected to a source of the fifth MOS transistor and a source connected to the second power supply terminal;
the seventh MOS transistor of the second conductivity type having a drain connected to the second output terminal, a source connected to a gate of the sixth MOS transistor, and a gate connected to the gate of the fifth MOS transistor; and
the eighth MOS transistor of the second conductivity type having a drain connected to the source of the seventh MOS transistor, a source connected to the second power supply terminal, and a gate connected to a source of the fifth MOS transistor;
wherein the first input voltage terminal is connected to the first power supply terminal.

14. The semiconductor integrated circuit according to claim 12, wherein the first-level shift circuit comprises:
a first MOS transistor of the first conductivity type that has a source connected to a first input voltage terminal;
a second MOS transistor of the first conductivity type that has a source connected to a drain of the first MOS transistor a drain connected to the first output terminal, and a gate connected to the second power supply terminal;
a third MOS transistor of the first conductivity type that has a source connected to the first input voltage terminal;
a fourth MOS transistor of the first conductivity type that has a source connected to a drain of the third MOS transistor, a drain connected to the second output terminal, and a gate connected to the second power supply terminal;
a fifth MOS transistor of the second conductivity type that has a drain connected to the first output terminal and a gate connected to the first power supply terminal;
a sixth MOS transistor of the second conductivity type that has a drain connected to a source of the fifth MOS transistor and a source connected to the second power supply terminal;
a seventh MOS transistor of the second conductivity type that has a drain connected to the second output terminal, a source connected to a gate of the sixth MOS transistor, and a gate connected to the gate of the fifth MOS transistor; and
an eighth MOS transistor of the second conductivity type that has a drain connected to the source of the seventh MOS transistor, a source connected to the second power supply terminal, and a gate connected to the source of the fifth MOS transistor;
the second-level shift circuit comprises:
a ninth MOS transistor of the first conductivity type that has a source connected to the first input voltage terminal and a gate connected to a gate of the third MOS transistor;
a tenth MOS transistor of the first conductivity type that has a source connected to a drain of the ninth MOS transistor, a drain connected to a gate of the first MOS transistor, and a gate connected to the output of the second inverter;
an eleventh MOS transistor of the first conductivity type that has a source connected to the first input voltage terminal and a gate connected to the gate of the first MOS transistor;
a twelfth MOS transistor of the first conductivity type that has a source connected to a drain of the eleventh MOS transistor, a drain connected to the gate of the ninth MOS transistor, and a gate connected to the output of the first inverter;
a thirteenth MOS transistor of the second conductivity type that has a drain connected to the drain of the tenth MOS transistor, a source connected to the second power supply terminal, and a gate connected to the output of the second inverter; and
a fourteenth MOS transistor of the second conductivity type that has a drain connected to the drain of the twelfth MOS transistor, a source connected to the second power supply terminal, and a gate connected to the output of the first inverter.

15. The semiconductor integrated circuit according to claim 14, wherein
the first and second augmenting MOS transistors, the first through fourth MOS transistors, and the ninth through twelfth MOS transistors are pMOS transistors;
the third and fourth augmenting MOS transistors, the fifth through eighth MOS transistors, and the thirteenth and fourteenth MOS transistors are nMOS transistors;
the first power supply terminal is supplied with a power supply voltage;
the first input voltage terminal is supplied with a voltage higher than the power supply voltage;
the second power supply terminal is supplied with a ground voltage; and
the second input voltage terminal is supplied with a voltage lower than the ground voltage.

16. The semiconductor integrated circuit according to claim 14, wherein
the first and second augmenting MOS transistors and the first through fourth MOS transistors are pMOS transistors;
the third and fourth augmenting MOS transistors and the fifth through eighth MOS transistors are nMOS transistors;
the first power supply terminal is supplied with a power supply voltage;
the second power supply terminal is supplied with a ground voltage; and
the second input voltage terminal is supplied with a voltage lower than the ground voltage.

17. The semiconductor integrated circuit according to claim 13, wherein the first through fourth augmenting MOS transistors and the first through fourteenth MOS transistors each have a gate and a source connected to the gate.

18. The semiconductor integrated circuit according to claim 14, wherein the first through fourth augmenting MOS transistors and the first through eighth MOS transistors each have their gate connected to their source.

19. A method of generating a switch signal for a switching circuit, the method comprising:
receiving a control signal at a control terminal connected to a first inverter;
inverting the control signal to generate a first signal;
inverting the first signal in a second inverter to generate a second signal;
shifting a voltage level of a first and second intermediate voltage to generate a first and second output voltage;
augmenting the first and second output voltages when a level of the control signal changes; and
supplying augmented first and second output voltages to a first output terminal and a second output terminal, respectively, wherein the first and second output terminals are connected to a switching circuit.

20. The method of claim 19, further comprising:
shifting a voltage level of the first and second signals to generate the first and second intermediate voltages.
